(19) United States
(12) Patent Application Publication
(10) Pub. No.: US 2009/0015120 A1
(43) Pub. Date: Jan. 15, 2009

(54) HEAT DISSIPATION DEVICE FOR ELECTRONICS CABINET

(75) Inventors: TODD A. NEWHOUSE, ROHNERT PARK, CA (US); RICHARD F. GIANNI, HEALDSBURG, CA (US)

Correspondence Address: FITZPATRICK CELLA (TELLABS), 30 ROCKEFELLER PLAZA, NEW YORK, NY, 10112-3800, US

(73) Assignee: TELLABS PETALUMA, INC., NAPERVILLE, IL (US)

(21) Appl. No.: 11/777,414

(22) Filed: Jul. 13, 2007

(51) Int. Cl. H05K 5/00; H05K 7/20

(52) U.S. Cl. 312/236; 454/184

(57) ABSTRACT

A cabinet includes a housing for housing equipment, and a heat dissipation device for dissipating heat in the housing. At least a part of the heat dissipation device is formed integrally with at least a part of the housing. The heat dissipation device includes a fluid passageway adjacent the housing. The fluid passageway includes first and second surface portions, together defining an enclosing structure surrounding an interior space, and first and second openings in the enclosing structure. The first surface portion defines a boundary between the interior space and a region containing the equipment. The first and second openings are provided in respective locations not on the first surface portion. Fluid is caused to flow into the first opening, through the interior space of the enclosing structure, and out of the second opening by means of convection, dissipating heat from the first region.

### BACKGROUND OF THE INVENTION

1. Field of the Invention

This invention generally relates to heat dissipation devices and, more particularly, to heat dissipation devices for cabinets containing electronic equipment, especially such a cabinet having an environmentally hardened housing.

2. Description of the Related Art

Telecommunications equipment is commonly housed in electronics cabinets kept outside in residential and commercial neighborhoods. Examples of such a cabinet are given in U.S. application Ser. No. 11/175,754 which is hereby incorporated herein by reference. The cabinets are environmentally hardened, e.g., made watertight, airtight, weatherproof, etc. to prevent water, dust, insects, etc. from entering the cabinets and adversely affecting the equipment inside the cabinets.

When operating as intended, the telecommunications equipment generates heat. In addition, heat from the surrounding environment, e.g., the sun, may enter the cabinet. Because excessive heat can damage the equipment, it is in many cases necessary to release some of the heat that accumulates in the cabinet.

The need to release heat is rendered more acute by the fact that the cabinets are environmentally hardened, since such hardening makes it more difficult for heat to escape from the cabinets.

The need to release heat has also been rendered more acute by certain changes in the telecommunications equipment stored in the cabinets. As more telecommunications services are provided, a greater amount of electronic equipment is stored in a cabinet. As the technology for providing telecommunications advances, it is increasingly common for the electronic equipment to include active electronic equipment rather than only passive electronic equipment. Active electronic equipment generates more heat than passive equipment.

Accordingly, it would be useful to provide a heat dissipation device for such electronics cabinets. As the demand for advanced telecommunication services increases and more and more customers require such electronics cabinets, there is an increasing need for a heat dissipation device that can be manufactured at a low cost, has a long useful life, and requires a minimum of maintenance. These goals can be achieved, at least in part, by simplifying the design of the heat dissipation device and by employing materials that are inexpensive but durable and with good thermal properties.

### SUMMARY OF THE INVENTION

According to an example embodiment of the present invention, there is provided a cabinet including a housing for housing equipment and a heat dissipation device for dissipating heat in the housing. At least a part of the heat dissipation device is formed integrally with at least a part of the housing. The heat dissipation device includes a first surface portion, a second surface portion, a first opening and a second opening. The first and second openings are provided in respective locations other than on the first surface portion. The first and second surface portions together define an enclosing structure surrounding an interior space serving as a fluid passageway. The first surface portion further defines a boundary between the interior space and a region containing the equipment. Each of the first and second openings is an opening in the enclosing structure. The heat dissipation device is adapted for fluid to flow into the first opening, through the interior space of the enclosing structure, and out of the second opening, for dissipating heat from the region.

According to an aspect of the example embodiment, the first opening is located below the second opening and, when a temperature of the region exceeds a temperature of the interior space, fluid is caused to flow into the first opening, through the interior space of the enclosing structure, and out of the second opening, by means of natural convection.

According to another aspect of the example embodiment, the cabinet is adapted to be mountable to a structure, at least a part of the cabinet is environmentally hardened, the first and second openings communicate with the ambient atmosphere, the fluid flows into the first opening from the ambient atmosphere, and the fluid is ambient air.

According to still another aspect of the example embodiment, the first opening includes a plurality of slots and the second opening includes a plurality of slots.

According to still another aspect of the example embodiment, the first opening is located at a lower end portion of the second surface portion, and the second opening is located at an upper end portion of the second surface portion.

According to still another aspect of the example embodiment, the cabinet is made of at least a plastic material.

According to still another aspect of the example embodiment, the housing houses electronic equipment.

According to still another aspect of the example embodiment, the cabinet is formed, at least in part, by injection molding.

According to a further example embodiment of the present invention, there is provided a cabinet including a housing for housing equipment and a heat dissipation device for dissipating heat in the housing. At least a part of the heat dissipation device is formed integrally with at least a part of the housing. The heat dissipation device includes a first surface portion, a second surface portion, a third surface portion, a first opening and a second opening. The first and second openings are provided in respective locations other than on the first surface portion. The first and second surface portions together define an enclosing structure surrounding an interior space. The first surface portion further defines a boundary between the interior space and a region containing the equipment. The third surface portion is disposed in the interior space between the first surface portion and the second surface portion to define an enclosing substructure surrounding an interior subspace serving as a fluid passageway. Each of the first and second openings is an opening in the enclosing substructure. The heat dissipation device is adapted for fluid to flow into the first opening, through the interior subspace of the enclosing substructure, and out of the second opening, for dissipating heat from the region.

According to an aspect of the further example embodiment, the first opening is located below the second opening and, when a temperature of the region exceeds a temperature of the interior subspace, fluid is caused to flow into the first opening, through the interior subspace of the enclosing substructure, and out of the second opening, by means of natural convection.

According to another aspect of the further example embodiment, the fluid passageway is located between the second surface portion and the third surface portion, and other than between the first surface portion and the third surface portion.

According to still another aspect of the further example embodiment, a gap is provided between the first surface portion and the third surface portion.

According to still another aspect of the further example embodiment, the third surface portion is impenetrable by air and/or water.

According to still another aspect of the further example embodiment, the cabinet is adapted to be mountable to a structure, at least a part of the cabinet is environmentally hardened, the first and second openings communicate with the ambient atmosphere, the fluid flows into the first opening from the ambient atmosphere, and the fluid is ambient air.

According to still another aspect of the further example embodiment, the first opening includes a plurality of slots and the second opening includes a plurality of slots.

According to still another aspect of the further example embodiment, the first opening is located at a lower end portion of the second surface portion, and the second opening is located at an upper end portion of the second surface portion.

According to still another aspect of the further example embodiment, the cabinet is made of at least a plastic material.

According to still another aspect of the further example embodiment, the third surface portion is made of plastic or metal.

According to still another aspect of the further example embodiment, the housing houses electronic equipment.

According to still another aspect of the further example embodiment, the cabinet is formed, at least in part, by injection molding.

According to a still further example embodiment of the present invention, there is provided a heat dissipation device, attachable to a housing, for dissipating heat in the housing. The heat dissipation device includes a first surface portion, a second surface portion, a first opening and a second opening. The first and second openings are provided in respective locations other than on the first surface portion. The first and second surface portions together define an enclosing structure surrounding an interior space serving as a fluid passageway. The first surface portion further defines a boundary between the interior space and a region inside the housing. Each of the first and second openings is an opening in the enclosing structure. The heat dissipation device is adapted for fluid to flow into the first opening, through the interior space of the enclosing structure, and out of the second opening, for dissipating heat from the region, by means of natural convection alone.

According to an aspect of the still further example embodiment, at least a part of the heat dissipation device is formed integrally with at least a part of the housing.

According to another aspect of the still further example embodiment, the first and second openings communicate with the ambient atmosphere, the fluid flows into the first opening from the ambient atmosphere, and the fluid is ambient air.

According to still another aspect of the still further example embodiment, the heat dissipation device is made of at least a plastic material.

According to still another aspect of the still further example embodiment, the heat dissipation device is formed, at least in part, by injection molding.

A better understanding of these and other aspects, features, and advantages of the invention may be had by reference to the drawings and to the accompanying description, in which preferred embodiments of the invention are illustrated and described.

### BRIEF DESCRIPTION OF THE DRAWINGS

FIG. 1 is a front and side perspective view of a cabinet in a closed state, according to an example embodiment of the present invention.

FIG. 2 is a perspective view of the interior of the cabinet of FIG. 1, in an opened state.

FIG. 3 is a rear and side perspective view of the closed cabinet of FIG. 1.

FIG. 4 is a front and side perspective view of the closed cabinet, as in FIG. 1, with a portion of the structure shown as being cut away.

FIG. 5 is a perspective view of the interior of a cabinet in an opened state, with a portion of the structure shown as being cut away, according to another example embodiment.

FIG. 6 is an exploded perspective view of the door, dividing wall and accessories thereof of the cabinet of FIG. 5.

FIG. 7 is a perspective front view of the closed cabinet of FIG. 5, with a portion of the structure shown as being cut away.

FIG. 8 is a front and side perspective view of a conventional electronics cabinet in a closed state.

FIG. 9 is a perspective view of the interior of the cabinet of FIG. 8 in an opened state.

FIG. 10 is a an exploded perspective view of the opened cabinet of FIG. 9, from which the door is omitted.

FIG. 11 is a rear and side perspective view of the closed cabinet of FIG. 8.

FIG. 12 is a partially exploded rear and side perspective view of the closed cabinet of FIG. 8.

Throughout the figures, like or corresponding reference numerals are used to identify like or corresponding parts.

### DETAILED DESCRIPTION OF THE PREFERRED EMBODIMENTS

While the present invention is applicable to an environmentally hardened electronics cabinet housing telecommunication equipment and mounted on the exterior of a house or other structure located out of doors, its applicability is not thus limited. The present invention can be applied to any container containing heat that needs to be released, such as but not limited to a container containing heat-generating or non-heat-generating equipment designed to function below a particular threshold temperature. Such a container could contain a source of heat (e.g., heat-generating equipment), and/or it could be heated by a source of heat external to the container.

One example application of example embodiments of the invention provides heat dissipation for optical network terminals. With the use of fiber optic cables to provide, e.g., telephone, television and internet services, optical network terminals are used, e.g., to convert optical signals to electrical signals and vice versa. Of course, example embodiments of the present invention also are applicable as heat dissipation devices for other types of telecommunications equipment and other electronic equipment.

The following terminological remarks apply to both the specification and the claims of this application.

The term “container” is intended to refer to anything that contains something, and is not to be taken as limited with respect to size, shape, purpose, object contained, etc. Moreover, the term “container” is intended to subsume both full and partial containers, including, e.g., containers that may be open to the exterior of the container, containers the contents of which may be able to exit the containers or may not be completely inside the containers, and the like. A non-limiting example of a partial container would be a box lacking a top or a spherical net. It is understood that the usage herein of the term “container” may be deemed to deviate from at least some common usage of that term.

As with the term container, so too other similar or related terms are also used herein in the same broad, expansive sense, without the limitations that may be deemed to attach thereto in some common usage. In particular, the terms “contain,” “enclose,” “enclosure,” “surround,” and the like, as well as grammatical variants of such terms, are to be taken as encompassing the concepts of “fully or partially contain,” “fully or partially enclose,” “full or partial enclosure,” “fully or partially surround,” and the like, respectively.

The term “surface” or the like as used herein is also to be construed in a broad, expansive manner. For example, a surface need not be flat, but could be curved, angled, etc. For another example, a given surface or surface portion need not be entirely distinct from a different surface or surface portion, but two different surfaces or surface portions could run into each other, overlap, be portions of the same single surface, etc. These examples are not to be taken as an exhaustive or comprehensive account of the breadth (or absence of restrictions placed on) terms such as “surface.”

The term “fluid” as used herein is also to be understood in a broad, expansive manner, covering gases, liquids, and other matter capable of flowing.

The term “equipment” as used herein is also to be understood in the broadest possible sense. It covers, for example, mechanical, electrical, and other types of equipment, active and passive equipment, etc.

Relative terms such as “front,” “rear,” “top,” “bottom,” etc. are used herein with reference to the standard mounting orientation of an electronics cabinet, which will be understood by one of skill in the art.

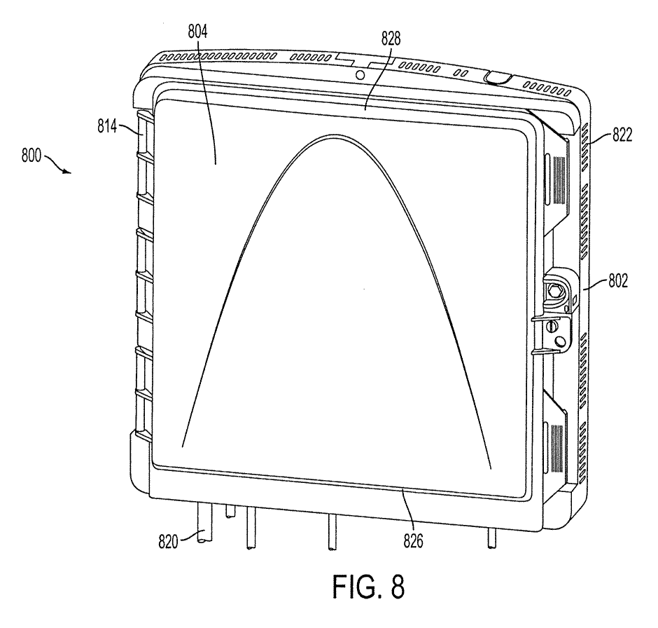

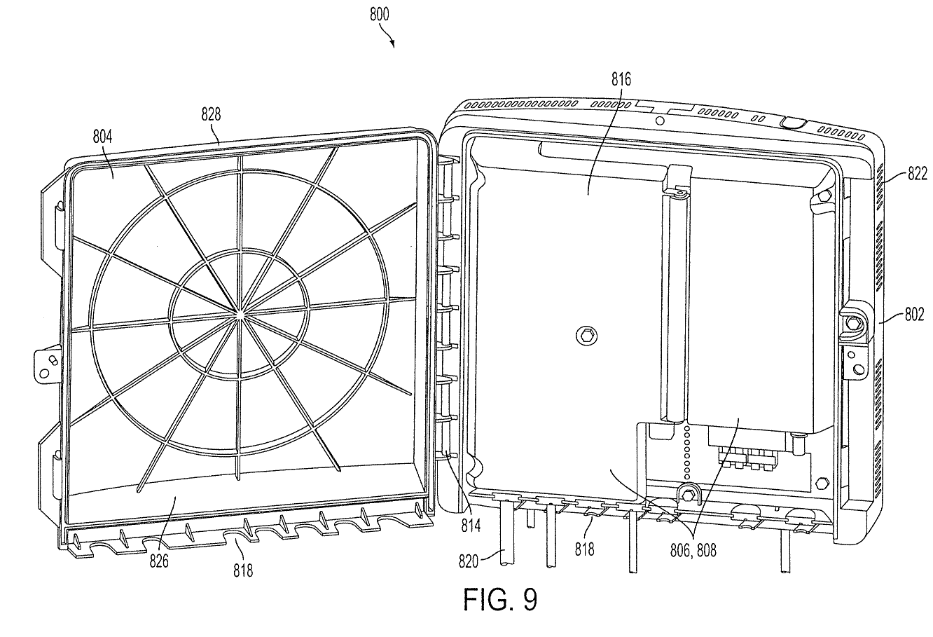

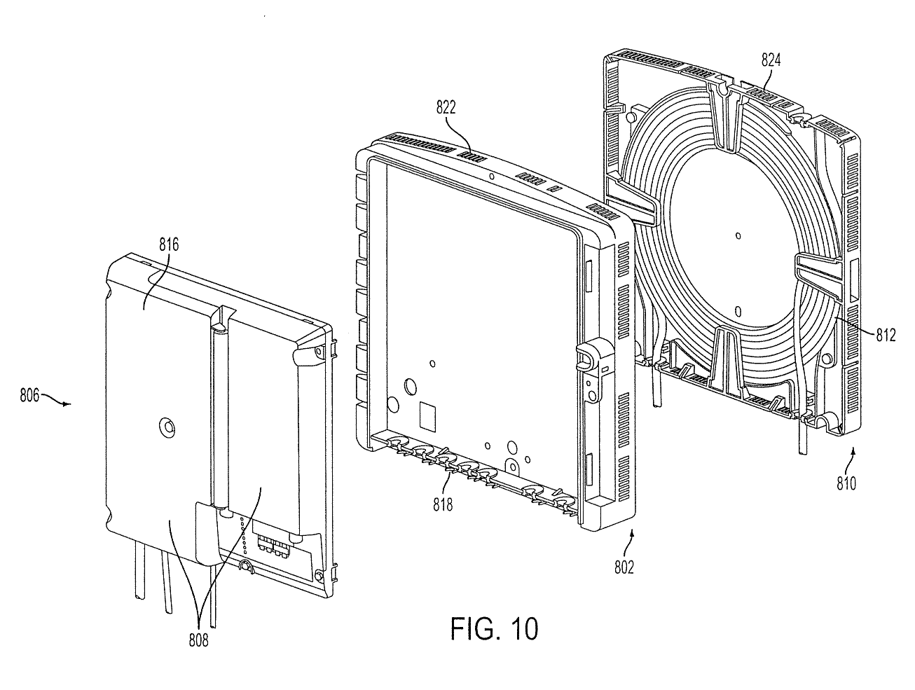

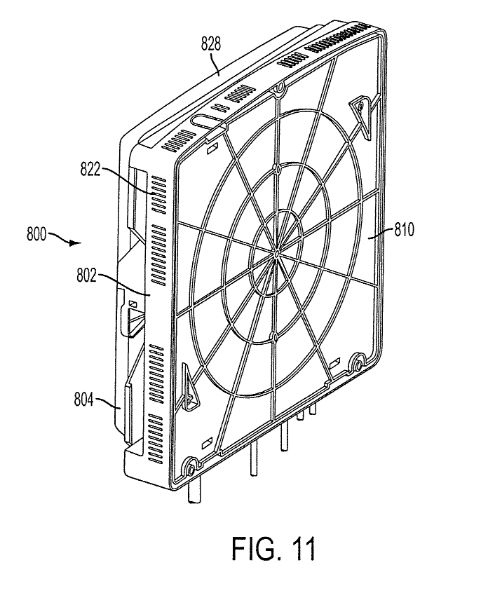

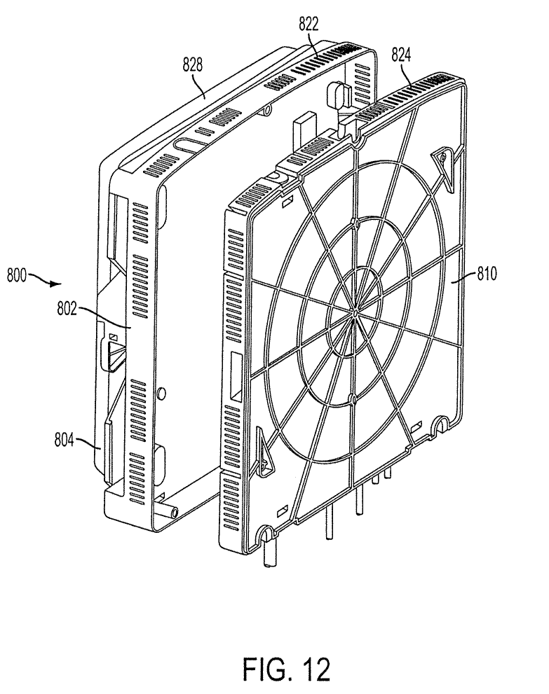

FIGS. 8-12 are perspective views showing an example of a conventional electronics cabinet for housing telecommunication equipment and for being mounted on the exterior of a house or other structure. FIG. 8 is a front and side view of a cabinet in a closed state. FIG. 9 is a view of the interior of the cabinet, in an opened state. FIG. 10 is an exploded view of the open cabinet, in which view the door is omitted. FIG. 11 is a rear and side view of the closed cabinet. FIG. 12 is a partially exploded rear and side view of the closed cabinet.

As shown in FIGS. 8-12, an electronics cabinet 800 includes a housing 802 including a door 804, an electronics module 806 including an inner housing 808 containing electronics equipment (not shown), and a cable storage unit 810 for storing excess cable 812. (Door 804 may be deemed to be part of housing 802, but for ease of discussion door 804 and housing 802, or corresponding elements discussed in this application, may be discussed as if they are separate elements.) Housing 802 is provided with respective cavities into which electronics module 806 and cable storage unit 810 fit. Electronics cabinet 800 can be mounted at a rear thereof, i.e., at the rear of cable storage unit 810, to an exterior of a structure, while access to an interior of electronics cabinet 800 is provided by opening door 804 at the front of electronics cabinet 800. Any suitable mechanism for mounting electronics cabinet 800 to the exterior of a house or structure may be employed, as will be understood by those of skill in the art.

Door 804 is connected to housing 802 by hinges 814, although any other suitable fastening mechanism may be used. Electronics module 806 may include one or more additional housings within inner housing 808. In the illustrated example, an inner door 816 is provided on the left side of inner housing 808 for access to cable connections (not shown). Housing 802 and door 804 are provided with cut-outs 818 for accommodating cables 820 entering electronics cabinet 800 from the exterior. Electronics module 806 also includes such cut-outs (not shown) permitting cables 820 to be connected to the electronics equipment inside electronics module 806. In the illustrated example, air vents 822 are provided in housing 802 along substantially the entire peripheral portion thereof into which cable storage unit 810 fits, and air vents 824 are provided along substantially the entire periphery of cable storage unit 810. Air vents 822 and 824 are aligned with each other and serve to release heat generated by the electronics equipment inside electronics module 806, although cabinet 800 may be designed so that air vents 822 and 824 are partly aligned or non-aligned, and overlapping or non-overlapping.

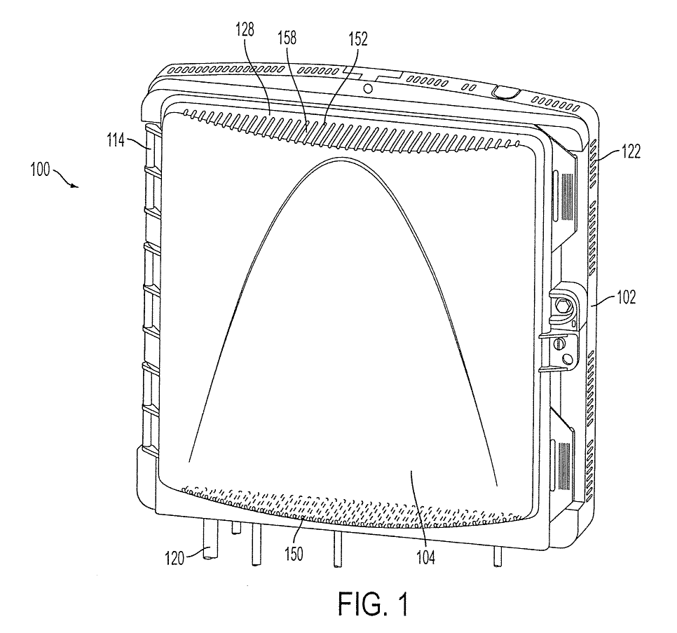

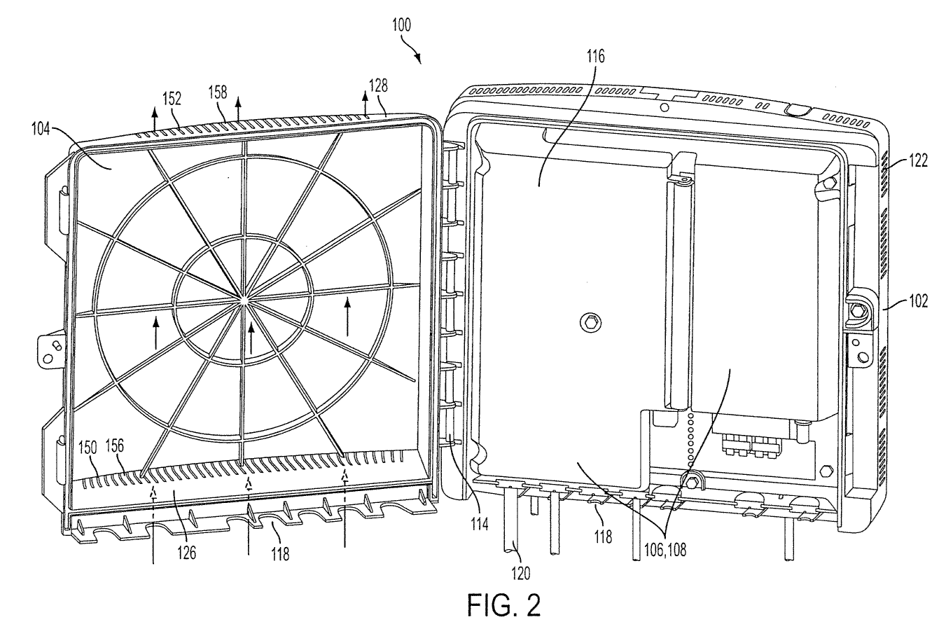

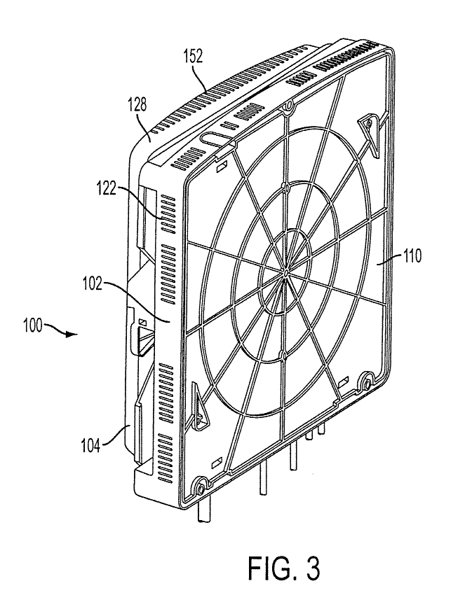

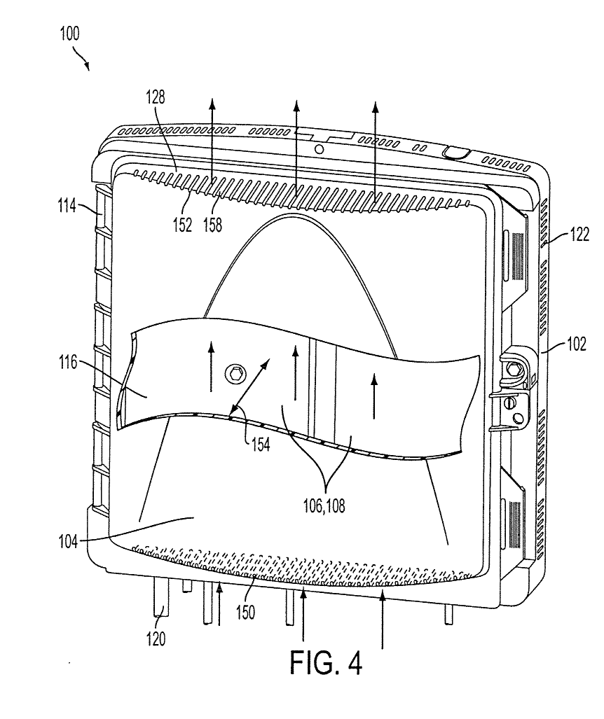

FIGS. 1-4 are perspective views illustrating a cabinet including a heat dissipation device, according to an example embodiment of the present invention. FIG. 1 is a front and side view of the closed cabinet. FIG. 2 is a view of the interior of the open cabinet. FIG. 3 is a rear and side view of the closed cabinet. FIG. 4 is a front and side view of the closed cabinet, as in FIG. 1, but with a horizontal mid-section of the door cut away to better illustrate a fluid passageway. It is noted that the conventional components shown in FIG. 10, discussed above, are applicable to at least some example embodiments of the invention.

Throughout the figures, corresponding reference numerals represent corresponding elements. Thus, reference numerals 100, 102, 104, 106, 108, 110, 112, 114, 116, 118, 120, 122, 124, 126 and 128 represent elements corresponding to those represented by reference numerals 800, 802, 804, 806, 808, 810, 812, 814, 816, 818, 820, 822, 824, 826 and 828, respectively. Analogous correspondences obtain in the case of other embodiments of the invention. Description of such corresponding elements will be provided to the extent that they differ from their previously-mentioned counterpart elements. In addition, it should be presumed that aspects of the prior art as described above with reference to FIGS. 8-12, which are not indicated by reference numerals in those drawings (e.g., a mechanism for mounting electronics cabinet 800 to a house or structure, optional additional housings within inner housing 808, cable connections, cut-outs in electronics module 806 for accommodating cables, and the like), are also applicable to at least some example embodiments of the invention.

While door 804 viewed from the outside of cabinet 800 may be slightly convex, door 104 of an example embodiment of the invention has a major central portion (main body) that is noticeably more convex, presenting an arced shape in a side-to-side direction of cabinet 100, as shown in FIGS. 1-4 (the arc protruding in a direction that appears perpendicularly outward from the plane of the paper in FIG. 1). Likewise, as shown in the illustrated example, upper end portion 128, which is a portion of the upper end of door 104 that is substantially perpendicular to the main body of door 104 and that faces upward in FIGS. 1-4, is larger and has a more arced shape (although truncated at both ends of the arc) than upper end portion 828 of door 804 (see FIGS. 8 and 9). Again, in this example, lower end portion 126 of door 104 (see FIG. 2), which is substantially symmetrical with upper end portion 128, forms likewise a larger, more arced shape (truncated at both ends) than lower end portion 826 of door 804.

This more convex configuration of door 104, with larger lower end portion 126 and larger upper end portion 128, accommodates a larger interior space between an inner surface of door 104 and (inner housing 108 of) electronics module 106 as compared with that of conventional cabinet 800, and further accommodates openings 150 provided in lower end portion 126 and corresponding openings 152 provided in upper end portion 128. The structure and functions of these example aspects of the present example embodiment of the invention will be described below.

In the illustrated example, openings 150 and 152 are slot-shaped, with their lengths extending primarily in the front-to-rear direction of cabinet 100. As shown, openings 150 and 152 extend slightly over the edge of lower and upper end portions 126 and 128, respectively, thus extending slightly in the vertical direction (up and down, respectively) on the front surface of the main body of door 104. (For ease of discussion, however, openings 150 and 152, and corresponding elements in other embodiments, may at times be discussed as if they extend solely in the front-to-rear direction of cabinet 100.) In the illustrated example, the slot-shaped openings 150 and 152 are formed by, or divided by, slats 156 and 158, respectively. In this example, openings 150 and 152 are shortest at the left and right ends of cabinet 100 and longest at the horizontal center of cabinet 100, with the length of openings 150 and 152 gradually and symmetrically increasing from either of these left and right ends to the horizontal center, in correspondence with the arced shapes of corresponding lower end portion 126 and upper end portion 128. The number, size, shape and any other aspect of the configuration of openings 150 and 152 need not be according to the illustrations of this example embodiment, but could be varied as will be understood by those of skill in the art in view of this description. Nor is it required to have a symmetry of configuration between openings 150 and openings 152.

When cabinet 100 (door 104) is closed, door 104 forms a seal with housing 102, e.g., by means of a gasket or the like, at the peripheries of door 104 and housing 102 (i.e., at the mutually facing peripheral surfaces of door 104 and housing 102). Other ways of sealing door 104 with housing 102 are possible, as would be known to one of skill in the art in view of this description.

When cabinet 100 (door 104) is closed, the open space in the interior of cabinet 100 can serve as fluid passageway 154. More specifically, in this example, fluid passageway 154 is the space bounded (when door 104 is closed) by (1) the inner surface of door 104 and (2) the inner surfaces of housing 102 (the inner surfaces of housing 102 are, to a large extent, the outer surfaces, facing closed door 104, of inner housing 108 of electronics module 106). The interior space serving as fluid passageway 154 may also be referred to as a gap. As will also be explained in detail below and as represented by the arrows in FIGS. 2 and 4, fluid (e.g., ambient air from outside of cabinet 100) is caused to enter openings 150, pass through fluid passageway 154, and exit fluid passageway 154 via openings 152 by means of convection, thereby dissipating heat contained in electronics module 106. (The arrows are provided in FIG. 2 to help the reader visualize fluid passageway 154 and the air flow even though fluid passageway 154, through which the air flow occurs, has been defined with the understanding that cabinet 100 is closed.)

In this example embodiment, openings 150 and openings 152 are open to the ambient air, and the fluid flowing through fluid passageway 154 is ambient air. However, in this or other embodiments of the invention, fluids other than air could be used, and openings 150 and 152 need not be open to the ambient air. It is also possible for the fluid to be forced air, or another fluid forcibly caused to flow through fluid passageway 154, as will be discussed in greater detail below.

In this example embodiment, the electronics equipment in electronics module 106 generates heat, rendering the air inside electronics module 106 hotter than the air inside adjacent fluid passageway 154. Under certain circumstances, the temperature of the air inside fluid passageway 154 may be the same as or similar to the temperature of the ambient air just outside of cabinet 100. Under certain circumstances, the temperature of the air inside fluid passageway 154 may be higher than the temperature of the ambient air just outside of cabinet 100; for example, if cabinet 100 is exposed to the sun or another heat source, the sun/heat source may heat the air inside fluid passageway 154 beyond the temperature of the ambient air just outside of cabinet 100. It is understood that, even in the presence of the sun or another heat source, the temperature inside electronics module 106 will be higher than the temperature inside fluid passageway 154.

The temperature difference, or so-called temperature rise, between the air inside electronics module 106 and the air in fluid passageway 154, with the former being hotter than the latter, causes a process of natural convection to occur in fluid passageway 154. The heated air contained inside electronics module 106 acts across inner housing 108 to heat up cooler air in fluid passageway 154. As air in fluid passageway 154 is heated, it becomes less dense than the surrounding air (e.g., air within fluid passageway 154 but farther away from electronics module 106, or air located outside of cabinet 100 and adjacent to openings 150 and 152). Due to the force of gravity and the fluid nature of air, the heated air, which is less dense, rises relative to the cooler, denser air. The rising heated air exits fluid passageway 154 through openings 152, creating a partial vacuum and drawing cooler air from outside of cabinet 100 into fluid passageway 154 through openings 150. The cooler air that has been drawn into fluid passageway 154 is heated by the heated air in electronics module 106, as before, and rises and exits fluid passageway 154, again creating the conditions that cause new, cooler air to enter fluid passageway 154. Thus, a continuous flow of air is established in fluid passageway 154 so long as the air inside electronics module 106 is hotter than the air inside fluid passageway 154. Thus, as has been described, a fluid-to-fluid (here, air-to-air) heat exchanger is established in cabinet 100, whereby heat is dissipated from electronics module 106.

While increasing the size of openings 150 and 152 would increase the air flow and consequent rate of heat transfer, in an example embodiment of the invention openings 150 and 152 are sized to substantially prevent foreign bodies such as insects, leaves, etc. from entering fluid passageway 154 and causing blockages or other potentially adverse effects.

Besides merely increasing the size of openings 150 and 152, certain configurations of openings 150 and 152 can also increase the air flow through fluid passageway 154 and thence the rate of heat transfer. For example, making slats 156 and 158 louvered or slanted can achieve this effect. The details of this and other configurations that may achieve this effect are understood to those of skill in the art in view of this description.

Also, modifying the size, shape or other aspects of the configuration of fluid passageway 154 may affect the air flow and concomitant rate of heat transfer. Any suitable modifications of the size, shape and other aspects of the configuration of fluid passageway 154 (including concomitant modifications of door 104, housing 102 and/or inner housing 108) are possible within the scope of this and other example embodiments of the invention.

In view of the fact, e.g., that the temperature of the electronics equipment is not necessarily uniform over its entire spatial extent, it is possible to increase heat dissipation by maintaining an air gap between the inner surface of inner housing 108 and the electronics equipment inside electronics module 106, rather than placing the electronics equipment in direct contact with inner housing 108. However, the cabinet may also be designed without such a gap, i.e., such that the electronic equipment is in direct contact with inner housing 108.

It is possible to include openings in inner housing 108 to further promote heat transfer from electronics module 106.

While in the above example embodiment, heat dissipation occurs by natural convection, the invention is not limited to this mode of operation. For example, forced convection could be used in addition to or instead of natural convection. An example of a forced convection arrangement would be the use of a fan to increase air flow and concomitant heat transfer. Where natural convection alone is used, it is understood that the exit from fluid passageway 154 (here, openings 152) should be located above the entrance to fluid passageway 154 (here, openings 150), in order for the risen hot air to exit, which permits the continual flow of air through fluid passageway 154. Such an arrangement is shown in FIGS. 1-4, with the air flow represented by the arrows in FIGS. 2 and 4. Thus, in the case of using natural convection alone, it is possible to change the locations of openings 150 and 152 so long as openings 152 are kept above openings 150. Where forced convection is used, it would be possible to arrange the heat dissipation device so that openings 152 are not located above openings 150. For example, such an arrangement could efficiently be used if combined with appropriate positioning of a fan or the like. For example, if a fan were arranged to produce a horizontal air flow, then the entrance and exit of fluid passageway 154 could be respectively located at two different positions horizontally rather than two different positions vertically.

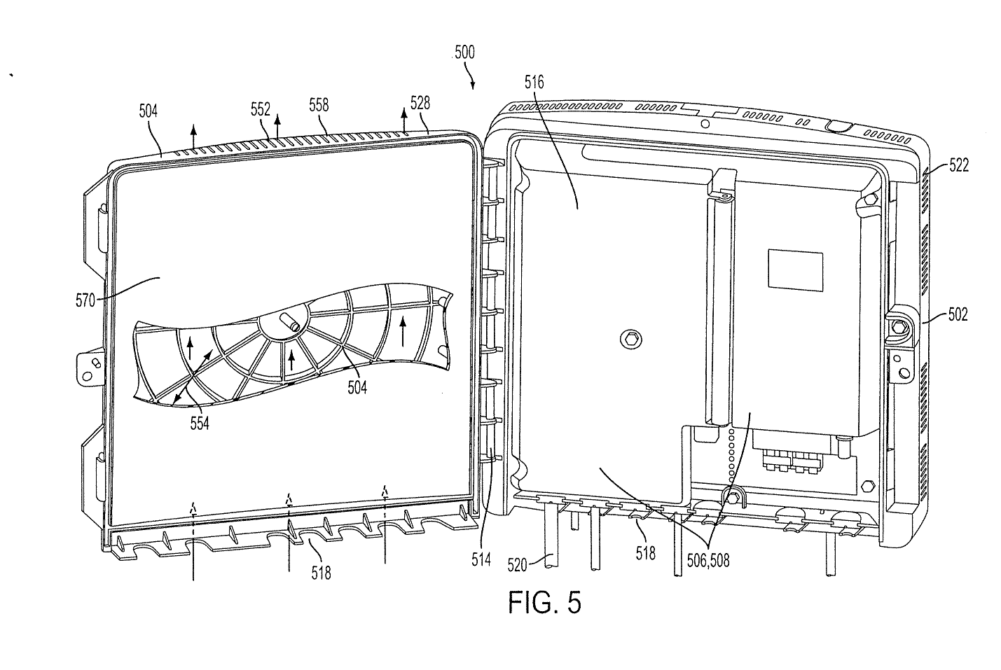

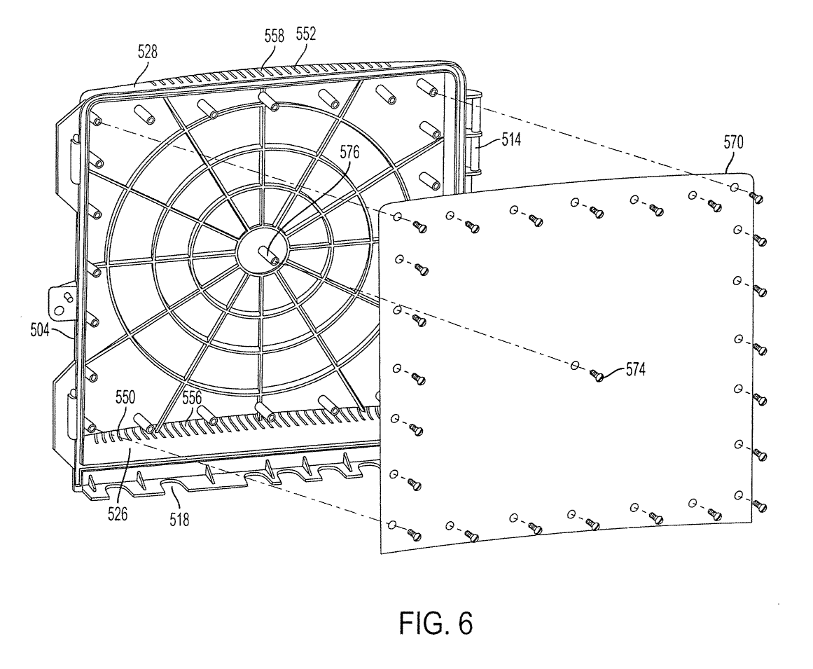

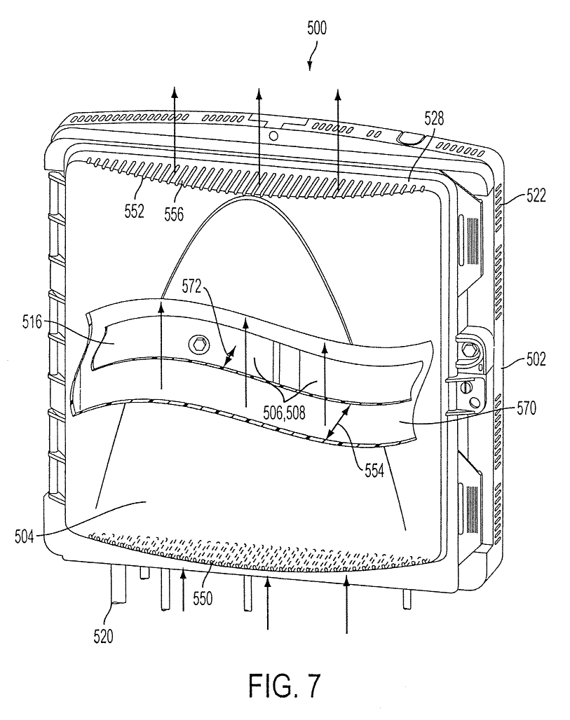

A cabinet including a heat dissipation device according to another example embodiment of the present invention is illustrated by FIGS. 1, 3 and 5-7 and will now be described. Aspects of this example embodiment that are the same as in the example embodiment shown in FIGS. 1-4 and that are not necessary for the description of distinctive aspects of this example embodiment will generally not be described. (Variations, modifications, and the like discussed above with reference to the example embodiment illustrated in FIGS. 1-4 may apply to this example embodiment, except as indicated to the contrary either explicitly or implicitly in view of distinctive features of this embodiment, as will be understood by one of skill in the art in view of this description. Such variations, modifications, and the like will generally not be discussed again in the context of this embodiment.) FIG. 5 is a perspective view of the interior of the open cabinet of this example embodiment, with a horizontal mid-section of a dividing wall (570) shown as being cut away to better illustrate the fluid passageway. FIG. 6 is an exploded perspective view of the door, dividing wall and their accessories shown in FIG. 5. FIG. 7 is a perspective front and side view of the cabinet of FIG. 5 shown in a closed position, with a horizontal mid-section of the door shown as being cut away to better illustrate the fluid passageway and, within the cut away section, a smaller horizontal mid-section of dividing wall 570 shown as being cut away to show another interior space and the electronics module (thus, in FIG. 7, the cut away portion of dividing wall 570 is reduced in size as compared to the cut away portion of dividing wall 570 in FIG. 5).

One feature of this example embodiment distinguishing it from the embodiment shown in FIGS. 1-4 is dividing wall 570. As seen most easily in FIGS. 5 and 6, in this example embodiment, dividing wall 570 is releasably attached at least at its perimeter to the perimeter of the interior of door 504. Further details of the mode of attachment will be provided below. Thus, dividing wall 570 and the interior of door 504 define an enclosure surrounding interior space 554.

When door 504 is closed (which state is shown in FIG. 7), dividing wall 570 lies between the interior of door 504 and the inner surfaces of housing 502 (the inner surfaces of housing 502 are, to a large extent, the outer surfaces, facing closed door 504, of inner housing 508 of electronics module 506). When door 504 is closed, the perimeter of dividing wall 570 (i.e., the side of the perimeter facing away from door 504) is in contact with the perimeter of the interior of housing 502. Further details of the mode of contact will be provided below. Thus, when door 504 is closed, dividing wall 570 and the inner surfaces of housing 502 define another enclosure surrounding another interior space 572 (shown in FIG. 7).

Interior spaces 554 and 572 may also be referred to as gaps. Further details of dividing wall 570 and its relations to other components of cabinet 500 will be provided below.

In this example embodiment openings 550 and 552 are provided in the same position as openings 150 and 152 (i.e., on lower and upper end portions 526 and 528, respectively, of door 504), which means that openings 550 and 552 lie horizontally between the main body (i.e., convex portion) of door 504 and dividing wall 570 (not between dividing wall 570 and inner surfaces of housing 502). Thus, in this example embodiment, interior space 554 (not interior space 572) serves as a fluid passageway (reference numeral 554 will hereafter be used to refer to the fluid passageway). In this example embodiment, then, fluid passageway 554 is formed by door 504 and dividing wall 570, in contrast to the example embodiment shown in FIGS. 1-4, in which fluid passageway 154 is formed by door 104 and the inner surface of housing 102 (contrast FIGS. 4 and 2 with FIGS. 7 and 5). Thus, the space making up fluid passageway 154 in the example embodiment shown in FIGS. 1-4 corresponds to the space making up fluid passageway 554, the space making up gap 472 and the space taken up by dividing wall 570 (except for its perimeter, which is attached to door 504) in the example embodiment shown in FIGS. 1, 3 and 5-7.

Dividing wall 570 may serve as an airtight and watertight barrier between fluid passageway 554 and interior space 572, and thence between fluid passageway 554 and electronics module 506. Providing gap (interior space) 572, rather than having dividing wall 570 be flush against inner housing 508, can increase heat dissipation from electronics module 506, in a manner and for reasons similar to that achieved by the above-noted gap between the inner surface of inner housing 108 and the electronics equipment inside electronics module 106. However, it is not required to have gap 572; it is possible to arrange dividing wall 570 to be flush against inner housing 508.

To accommodate electronics module 506 and gap 572, in this example embodiment dividing wall 570 is slightly convex in the same direction as door 504. Cabinet 500 could be designed so that dividing wall 570 is not convex, e.g., by omitting gap 572 or in other ways, as will be understood by one of skill in the art in view of this description. The size, shape and other aspects of the configuration of dividing wall 570 may be suitably modified for modifying the configuration of fluid passageway 554, accommodating electronics module 506 or other components of cabinet 500, or for other purposes, as will be understood by those of skill in the art in view of this description.

In the illustrated example, dividing wall 570 is formed as a piece separate from housing 502 and door 504, and is connected to door 504 by screws 574 screwed into cylindrical stand-offs 576 formed integrally with door 504. Cylindrical stand-offs 576, which pass through fluid passageway 554 transversely, may be provided at the center and equally spaced around the periphery of door 504, as shown. However, alternative arrangements of cylindrical stand-offs 576 are possible, so long as a sufficiently secure connection of dividing wall 570 to door 504 is maintained. Cylindrical stand-offs 576 may be threaded or not.

In alternative embodiments, dividing wall 570 may be fastened to door 504 by other mechanisms. For example, dividing wall 570 could be formed, e.g., by injection molding, as a single piece together with housing 502 and door 504, with a living hinge arrangement for connecting dividing wall 570 to door 504. As another alternative, dividing wall 570 could be connected to door 504 by a mechanism effecting an interference fit (e.g., a hook and snap arrangement), in which the two fitted elements are sealed in a joining process in which one of the fitted elements is distorted to accommodate the other. A variety of such interference fit mechanisms (including the above case in which the cylindrical stand-offs are not threaded) are known to those of skill in the art. Any other suitable manner of fastening could be used to join dividing wall 570 and door 504.

In the example embodiment illustrated in FIGS. 1-4, it was noted that door 104 forms a seal with housing 102 at the peripheries thereof when cabinet 100 (door 104) is closed. This aspect of the example embodiment illustrated in FIGS. 1-4 applies to the example embodiment illustrated in FIGS. 1, 3 and 5-7 with the following qualification. Dividing wall 570 can be arranged so that, when door 504 seals with housing 502, a perimeter portion of dividing wall 570 is sandwiched between a perimeter portion of door 504 and a perimeter portion of housing 502, thus keeping the perimeter portion of dividing wall 570 in intimate contact (not only with the perimeter portion of door 504 but also) with the perimeter portion of housing 502. Other mechanisms for keeping the perimeter portion of dividing wall 570 in intimate contact with that of housing 502 are possible, as would be known to one of skill in the art in view of this description.

Dividing wall 570 functions as a heat sink, increasing the rate of heat transfer from electronics module 506 to the fluid in fluid passageway 554. In one example embodiment, dividing wall 570 is made of a metal material, such as aluminum or an aluminum alloy, steel, copper, or another metal. In another example embodiment, dividing wall 570 is made of a plastic material, such as Valox™, which is a combination of PBT (polybutylene teraphthalate) and polycarbonate, or another plastic material. Dividing wall 570 can also be made of other materials.

The use of metal for dividing wall 570 may permit a greater rate of heat transfer as compared with the use of plastic. However, if dividing wall 570 is made of plastic, its heat transfer properties may be improved by forming dividing wall 570 to be a thin sheet. For example, if a plastic sheet approximately 1/32″ thick is used for dividing wall 570, the heat transfer properties of dividing wall 570 may approach those achieved when a metal sheet is used for dividing wall 570. However, if dividing wall 570 is made of plastic, it is not required to make dividing wall 570 thin.

Forming dividing wall 570 of metal may be more expensive than forming it of plastic. For example, machining the metal may be expensive relative to forming the plastic. If a sufficient number of cabinets are to be produced, then the use of injection molding to form dividing wall 570 of plastic may further reduce the cost as compared with metal.

In example embodiments of the invention, the components of cabinet 500 other than dividing wall 570 of the invention may also be made of Valox™, or another plastic material. It is desirable that the materials used for the cabinet have good formability, impact strength, weatherability, and stability under load. For use out of doors or otherwise in the potential presence of water, plastic provides the advantage, among other things, of not being subject to rust. However, the components of cabinet 500 other than dividing wall 570 need not be made of plastic, but could be made of any suitable material(s), as will be understood of those of skill in the art in view of this description.

Again, for example embodiments of the invention, the entire cabinet or any part(s) thereof may be formed by an injection molding process, in which, e.g., a thermoplastic material is heated. When manufactured by injection molding, the housing (102, 502) and the door (104, 504) may be formed as a single piece, but this is not required. In the case of embodiments having dividing wall 570, if dividing wall 570 is formed of plastic, it too can be formed together with the housing and the door as a single piece, but this is not required. If a sufficient number of cabinets are to be produced, injection molding reduces the cost of manufacture. Thus, making dividing wall 570 of plastic may simplify and further reduce the cost of manufacture when injection molding is used for manufacturing the cabinet (100, 500). Although injection molding provides certain advantages, any appropriate method of manufacture may be used for any embodiment of the invention, as will be understood by those of skill in the art in view of this description.

In at least some example embodiments of the invention, the cabinet, e.g., when used to house telecommunications equipment or other electronic equipment, may be designed to comply with pertinent government (e.g., FCC) regulations and industry standards, such as but not necessarily limited to those pertaining to emission of electromagnetic radiation, weather tightness, and fire and safety. Some such government regulations and industry standards may require the cabinet to be environmentally hardened.

In at least some example embodiments of the invention, the cabinet or any part(s) thereof may be environmentally hardened to meet or exceed governmental regulations and/or industry standards. The cabinet or any part(s) thereof may be environmentally hardened in ways not covered by such regulations and standards. Environmental hardening provided to the cabinet or parts thereof may include rendering the cabinet watertight, airtight, weatherproof, etc. Environmental hardening provided to the cabinet or parts thereof may protect the cabinet against weather conditions such as hurricane-driven rain, intense solar heat, etc. Environmental hardening provided to the cabinet or parts thereof may also protect the cabinet against household chemicals and, more generally, what may be deemed common circumstances of use in a residential, commercial or other environment. Environmental hardening provided to the cabinet or parts thereof may also protect the cabinet against intrusion by foreign matter, such as dust, insects, etc. The term “environmental hardening” is understood to cover any or all of these types of protection, but it is not necessarily limited to these types of protection only.

Environmental hardening may be provided by material properties of any or all of the components of the cabinet, e.g., the door, the housing, the inner housing, the dividing wall, etc. Further details as to what materials provide (what types of) environmental hardening, or how to provide environmental hardening, are known by those of skill in the art.

Since the door of the cabinet is provided with openings (150, 550, 152, 552), which may permit intrusion into the fluid passageway (154, 554) of water, air, heat, and foreign bodies up to a certain size, environmental hardening properties may be provided, among other places, in the dividing wall and/or inner housing. In example embodiments of the invention having a dividing wall, environmental hardening may be provided in only one (rather than both) of the dividing wall and the front of the inner housing, if desired, e.g., to reduce cost. Where example embodiments of the invention are used indoors or in a setting to some degree sheltered from the elements, less environmental hardening will be required and therefore less environmental hardening may be provided, if desired, e.g., in order to reduce cost. It is not required to provide environmental hardening to the cabinet or any part(s) thereof, particularly where the cabinet is to be used in indoors or in a setting that is to some degree sheltered from the elements.

For security, the cabinet or a part thereof may be provided with a lock or other suitable security mechanism to prevent unauthorized access to the interior. The details of such security mechanisms are known to those of skill in the art.

One advantage provided by the invention is that it can provide effective heat dissipation without the use of fans or other equipment for producing forced convection. This advantage provides simplification and reduction of cost of manufacture, as well as enhanced durability and reliability of the device. Since there is not an issue of breakdown of fans or other such equipment, the maintenance-free life of the device may be extended. Of course, the invention may also be used with fans or such other equipment for producing forced convection.

One of ordinary skill in the art will realize that modifications and variations, including but not limited to those discussed above, are possible within the spirit and scope of the present invention. The invention is intended to be limited in scope only by the accompanying claims, which should be accorded the broadest interpretation so as to encompass all such modifications, and equivalent structures and functions.

What is claimed is:

1. A cabinet comprising:
a housing for housing equipment; and
a heat dissipation device to dissipate heat in the housing, at least a part of the heat dissipation device being formed integrally with at least a part of the housing, the heat dissipation device including a first surface portion, a second surface portion, a first opening and a second opening provided in respective locations other than on the first surface portion,
wherein the first and second surface portions together defines an enclosing structure surrounding an interior space serving as a fluid passageway, the first surface portion further defines a boundary between the interior space and a region containing the equipment, each of the first and second openings being an opening in the enclosing structure, and the heat dissipation device being adapted for fluid to flow into the first opening, through the interior space of the enclosing structure, and out of the second opening, to dissipate heat from the region.

2. A cabinet as claimed in claim 1, wherein the first opening is located below the second opening and, when a temperature of the region exceeds a temperature of the interior space, fluid is caused to flow into the first opening, through the interior space of the enclosing structure, and out of the second opening, by means of natural convection.

3. A cabinet as claimed in claim 1, wherein the cabinet is adapted to be mountable to a structure, at least a part of the cabinet is environmentally hardened, the first and second openings communicate with the ambient atmosphere, the fluid flows into the first opening from the ambient atmosphere, and the fluid is ambient air.

4. A cabinet as claimed in claim 1, wherein the first opening comprises a plurality of slots and the second opening comprises a plurality of slots.

5. A cabinet as claimed in claim 2, wherein the first opening is located at a lower end portion of the second surface portion, and the second opening is located at an upper end portion of the second surface portion.

6. A cabinet as claimed in claim 1, wherein the cabinet is made of at least a plastic material.

7. A cabinet as claimed in claim 1, wherein the housing houses electronic equipment.

8. A cabinet as claimed in claim 1, wherein the cabinet is formed, at least in part, by injection molding.

9. A cabinet comprising:
a housing for housing equipment; and
a heat dissipation device for dissipating heat in the housing, at least a part of the heat dissipation device being formed integrally with at least a part of the housing, the heat dissipation device comprising a first surface portion, a second surface portion, a third surface portion, a first opening and a second opening, the first and second openings being provided in respective locations other than on the first surface portion, the first and second surface portions together defining an enclosing structure surrounding an interior space,
wherein the first surface portion further defines a boundary between the interior space and a region containing the equipment, the third surface portion is disposed in the interior space between the first surface portion and the second surface portion to define an enclosing substructure surrounding an interior subspace serving as a fluid passageway, each of the first and second openings being an opening in the enclosing substructure, and the heat dissipation device is adapted to enable fluid to flow into the first opening, through the interior subspace of the enclosing substructure, and out of the second opening, to dissipate heat from the region.

10. A cabinet as claimed in claim 9, wherein the first opening is located below the second opening and, when a temperature of the region exceeds a temperature of the interior subspace, fluid is caused to flow into the first opening, through the interior subspace of the enclosing substructure, and out of the second opening, by means of natural convection.

11. A cabinet as claimed in claim 9, wherein the fluid passageway is located between the second surface portion and the third surface portion, and other than between the first surface portion and the third surface portion.

12. A cabinet as claimed in claim 9, wherein a gap is provided between the first surface portion and the third surface portion.

13. A cabinet as claimed in claim 9, wherein the third surface portion is impenetrable by air and/or water.

14. A cabinet as claimed in claim 9, wherein the cabinet is adapted to be mountable to a structure, at least a part of the cabinet is environmentally hardened, the first and second openings communicate with the ambient atmosphere, the fluid flows into the first opening from the ambient atmosphere, and the fluid is ambient air.

15. A cabinet as claimed in claim 9, wherein the first opening comprises a plurality of slots and the second opening comprises a plurality of slots.

16. A cabinet as claimed in claim 10, wherein the first opening is located at a lower end portion of the second surface portion, and the second opening is located at an upper end portion of the second surface portion.

17. A cabinet as claimed in claim 9, wherein the cabinet is made of at least a plastic material.

18. A cabinet as claimed in claim 9, wherein the third surface portion is made of plastic or metal.

19. A cabinet as claimed in claim 9, wherein the housing houses electronic equipment.

20. A cabinet as claimed in claim 9, wherein the cabinet is formed, at least in part, by injection molding.

21. A heat dissipation device, attachable to a housing, for dissipating heat in the housing, the heat dissipation device comprising:
a first surface portion; and
a second surface portion, the first and second surface portions defining an enclosing structure surrounding an interior space serving as a fluid passageway, the first surface portion defining a boundary between the interior space and a region inside the housing, and a first opening and a second opening are provided in respective locations other than on the first surface portion, each of the first and second openings being an opening in the enclosing structure,
wherein the heat dissipation device is adapted for fluid to flow into the first opening, through the interior space of the enclosing structure, and out of the second opening, to dissipate heat from the region, by means of natural convection alone.

22. A heat dissipation device according to claim 21, wherein at least a part of the heat dissipation device is formed integrally with at least a part of the housing.

23. A heat dissipation device according to claim 21, wherein the first and second openings communicate with the ambient atmosphere, the fluid flows into the first opening from the ambient atmosphere, and the fluid is ambient air.

24. A heat dissipation device according to claim 21, wherein the heat dissipation device is made of at least a plastic material.

25. A heat dissipation device according to claim 21, wherein the heat dissipation device is formed, at least in part, by injection molding.
